(19) United States
(12) Patent Application Publication
(10) Pub. No.: US 2011/0147069 A1
(43) Pub. Date: Jun. 23, 2011

(54) Multi-tiered Circuit Board and Method of Manufacture

(75) Inventors: Richard A. Quackenbush, Vestal, NY (US); James Su, Endicott, NY (US); John T. Wilson, Vestal, NY (US)

(73) Assignee: INTERNATIONAL BUSINESS MACHINES CORPORATION, Armonk, NY (US)

(21) Appl. No.: 12/642,020

(22) Filed: Dec. 18, 2009

(51) Int. Cl. H01R 12/04; H05K 3/02

(52) U.S. Cl. 174/266; 29/847

(57) ABSTRACT

The present invention provides a printed circuit board assembly that includes a first printed circuit board portion having a first thickness and including at least one plated through hole selectively electrically interconnecting electrically conductive layers of the printed circuit board assembly. A second printed circuit board portion is also provided that has a second thickness which is less than the first thickness and further includes another a second plated through hole array exposed on a surface of the second printed circuit board portion.

### BACKGROUND OF THE INVENTION

1. Technical Field

The present invention relates to printed circuit boards. In particular, the present invention relates to printed circuit boards and their fabrication electronic interconnection.

2. Description of the Related Art

Printed circuit boards or printed circuit cards provide a convenient structure of mechanical support and electrical interconnection for modern electronic devices. Printed circuit boards consist of layers of electrically conductive paths, tracks or traces commonly etched from thin copper sheets laminated on a non-conductive layer or substrate commonly fabricated from resin.

As modern technology advances, thicker printed circuit boards are required because of the increased number of electrical path layers required by the more complex electronic devices and the increased complex functionality required of these printed circuit boards.

### SUMMARY

In accordance with the present invention, a printed circuit board assembly is provided that includes a first printed circuit board portion of a first thickness having at least one plated through hole selectively electrically interconnecting electrically conductive layers of the printed circuit board assembly and a second printed circuit board portion having a second thickness which is less than the first thickness and further including another second plated through hole exposed on a surface of the second printed circuit board portion.

### BRIEF DESCRIPTION OF THE DRAWINGS

The present invention may be better understood, and its numerous objects, features, and advantages made apparent to those skilled in the art by referencing the accompanying drawings.

FIG. 1 is a process block diagram for fabricating a two tier circuit board having two sub-composite circuit cards.

FIG. 2 is an isometric view of the two tier circuit board having two sub-composite circuit cards.

FIG. 3 is a top view of the two tier circuit board having two sub-composite circuit cards.

FIG. 4 is a cross section view of a portion of the circuit board of FIG. 3.

FIG. 5 is the cross section view of a portion of the circuit board of FIG. 4 including a connector.

FIG. 6 is a process block diagram for a single printed circuit board fabricated to have two tiers.

FIG. 7 is an isometric view of the single printed circuit board fabricated to have two tiers.

FIG. 8 is a top view of the single printed circuit board fabricated to have two tiers.

FIG. 9 is a cross section view of a portion of the printed circuit board of FIG. 8 illustrating a plated through hole interconnection.

FIG. 10 is the cross section view of a portion of the printed circuit board of FIG. 9 further illustrating printed circuit board connector.

FIG. 11 is a block process diagram for a single printed circuit board fabricated to have two tiers with further fabrication of plated through hole structure.

FIG. 12 is an isometric view of the single printed circuit board fabricated to have two tiers.

FIG. 13 is a top view of the single printed circuit board fabricated to have two tiers illustrated in FIG. 12.

FIG. 14 is a cross section view of a portion of the printed circuit board of FIG. 13 illustrating an enhanced plated through hole interconnection.

FIG. 15 is the cross section view of FIG. 13 further illustrating a connector mounted on the printed circuit board.

### DETAILED DESCRIPTION

The following is intended to provide a detailed description of an example of the invention and should not be taken to be limiting of the invention itself. Rather, any number of variations may fall within the scope of the invention, which is defined in the claims following the description.

The present invention provides for a printed circuit board having at least two thicknesses or circuit board depths that are termed tiers and the present invention also provides for a method and a computer program for fabricating or manufacturing this multiple tiered printed circuit board. Modern printed circuit cards include many electrically conductive layers with corresponding non-conductive support layers. As such the printed circuit boards become thicker. These printed circuit boards must also be fabricated to provide interconnections to printed circuit board connectors so that these printed circuit boards can be assembled or matted into rack assemblies of electronic systems. Currently commercially available connectors provide a maximum thickness limitation for printed circuit boards. The present invention provides the ability to use connectors requiring a specific limited printed board thickness while providing a printed circuit board thickness much greater than this specific limited thickness.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction implementation system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction implementation system, apparatus, or device.

Program code embodied on a computer readable medium may be transmitted using any appropriate medium, including but not limited to wireless, wire line, optical fiber cable, RF, etc. or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may be implemented entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which are implemented via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which are implemented on the computer or other programmable apparatus provide processes for implementing the functions/acts specified in the flowchart and/or block diagram block or blocks.

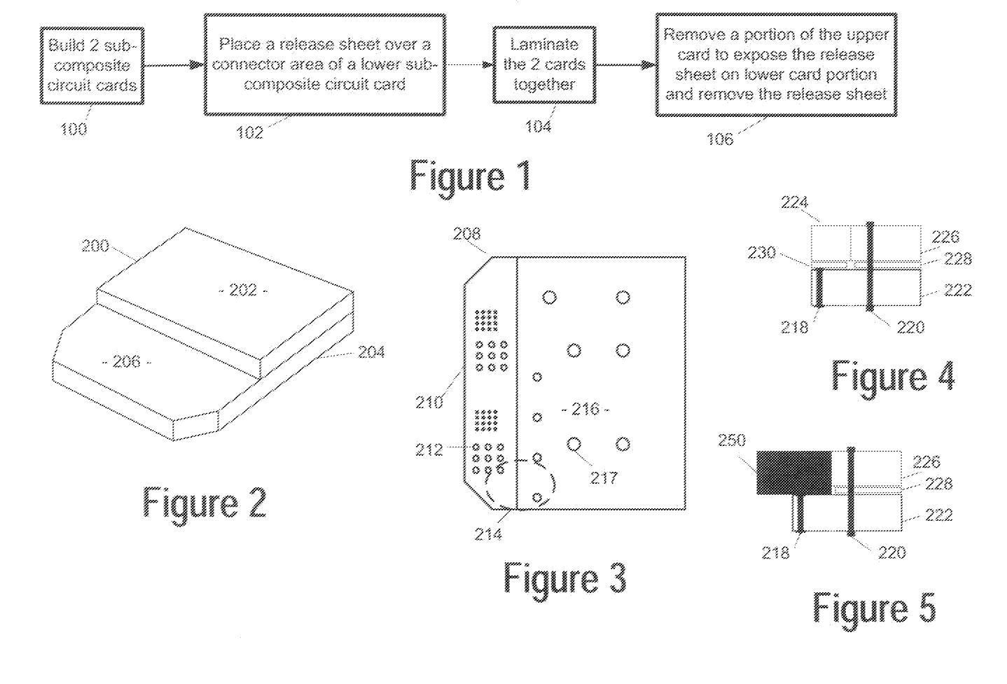

FIG. 1 is a block diagram illustrating the process for forming a two-tiered printed circuit board using sub-composite circuit cards. In the first step 100, two sub-composite circuit cards are manufactured. Each sub-composite printed circuit card includes multiple conductive layers interspaced between non-conductive cores or layers. In the preferred embodiment, the sub-composite cards will include plated through holes structures that selectively interconnect the electrically conductive layers as the required for electrical functionality. In step 102, a release sheet is placed over a portion of one of composite printed circuit boards. The release sheet covered portion is the portion of the sub-composite printed circuit board that will receive a printed circuit board connector. In step 104, both the sub-composite printed circuit boards are then laminated together. In step 106, a portion of the top sub-composite printed circuit board is removed to expose the release sheet. In the preferred embodiment, the removal of this top sub-composite printed circuit board portion is accomplished by a milling operation although other fabrication techniques may be used. The release sheet is then removed exposing the connective portions on the lower sub-composite printed circuit board that are now available for interconnection with the printed circuit board connector. This porting may include multiple plated through hole structures that selectively interconnect to the electrically conductive layers of both sub-composite printed circuit boards.

FIG. 2 is an isometric view of the two tiered circuit board structure 200 that results from the process of FIG. 1. Structure 200 is a two tier circuit board consisting of a sub-composite circuit board 204 located underneath sub-composite circuit board 202. The structure 200 includes an exposed area 206 which is used to attach to a printed circuit board connector. This printed circuit board structure 200 provides a thinner printed circuit board profile for the printed circuit board connector while providing a thicker portion with more non-conductive layers and electrically conductive layers.

The top view of the two tier printed circuit board structure of FIG. 2 is shown in FIG. 3. The printed circuit board structure 208 illustrates the thicker portion 216 including several plated through hole structures such as 217. The thinner portion of the printed circuit board 210 is shown to include several arrays of plated through hole structures such as 212. Area 214 illustrates a printed circuit board portion having a cross-sectional area that is shown in FIG. 4.

In FIG. 4, the cross-section of area 214 (FIG. 3) is shown to include the two sub-composite printed circuit boards 226 and 222 separated by a non-conductive lamination layer 228. Additionally, a plated through hole structure 220 selectively connecting electrically conductive layers in both the sub-composite printed circuit boards 222 and 226 is shown. Plated through hole structure 218 is shown electrically connecting conductive layers in the lower sub-composite printed circuit board 222. Above the plated through hole 218 is the release sheet 230. Area 224 of the sub-composite printed circuit board 226 is the area to be removed along with the release sheet 230 to expose the printed circuit board connector connection area 210 (FIG. 3). In the preferred embodiment a printed circuit board connector 250 (FIG. 5) is mounted above the surface 206 (FIG. 2) and is electrically connected to the plated through hole 218 (both FIGS. 4 and 5). This connector 250 provides electrical connection either to other printed circuit boards or other system connectors.

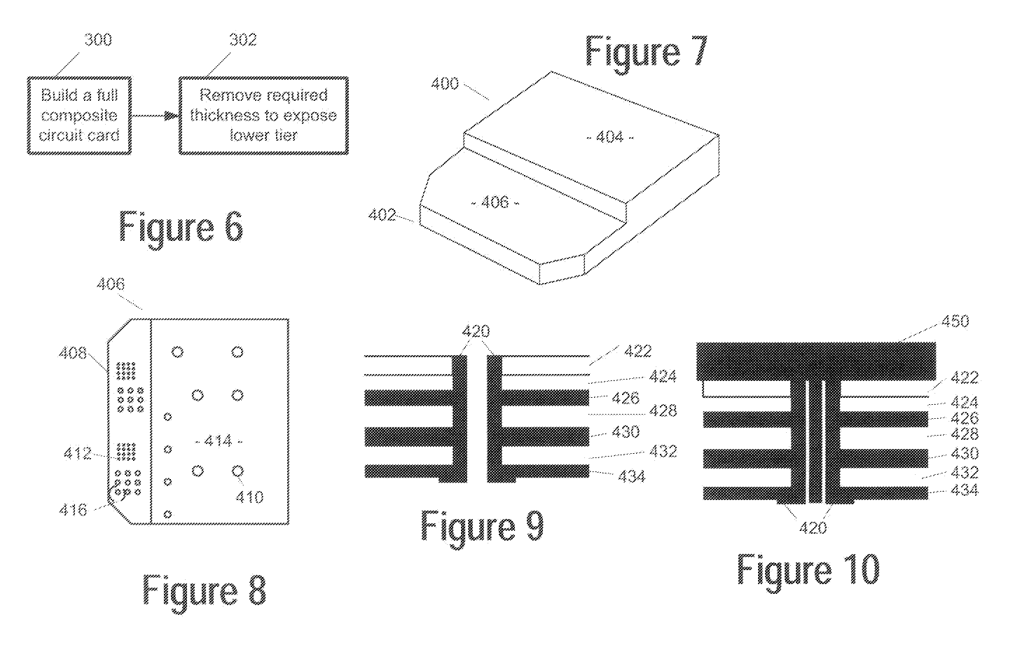

FIG. 6 is a process block diagram showing an alternative process to fabricate a two-tiered circuit board. In this process, step 300 provides that a full composite circuit board be constructed. Then, in the second step 302, a portion of the full composite circuit board is removed to provide a lower tier with a thinner required depth. In the preferred embodiment, the second step removal is accomplished by a milling operation to mill the lower tier to the desired thickness. Alternatively, the removal operation may be accomplish by a grinding or equivalent material removal operation. This provides a lower tier being fabricated and exposed for interconnection with a printed circuit board connector. The resulting printed circuit board structure is illustrated in FIG. 7 having printed circuit board 400 consisting of a lower tier 402 and an upper tier 404. Area 406 is the surface area that is provided for connection to a printed circuit board connector. It should also be noted that while the lower tier area 406 is bounded by a straight wall of the upper tier 404, the material removal operation may form other shapes such as a curved wall or wall shapes appropriately formed to receive a correspondingly shaped circuit board connector.

In FIG. 8, a top view of this two-tier circuit board structure is illustrated as printed circuit board 406. The lower tier 408 includes an array of plated through hole connections such as 412 that provide for interconnection to a printed circuit board connector. The top tier 414 also includes plated through holes such as 410 which selectively interconnect the electrically conductive layers of the full composite printed circuit board. A single plated through hole connector 416 in FIG. 8 is illustrated in cross-section in FIG. 9.

In FIG. 9, the top of the plated through hole structure is shown as 420 which is adjacent to a lamination area layer 422. The areas beneath the lamination layer 422 would include dielectric or non-conductive layers 424, 428 and 432 spaced between electrically conductive trace layers 426, 430 and 434. In FIG. 10, the cross-section or the printed circuit board is illustrated as including a connector 450 electrically connected to the plated through hole 420.

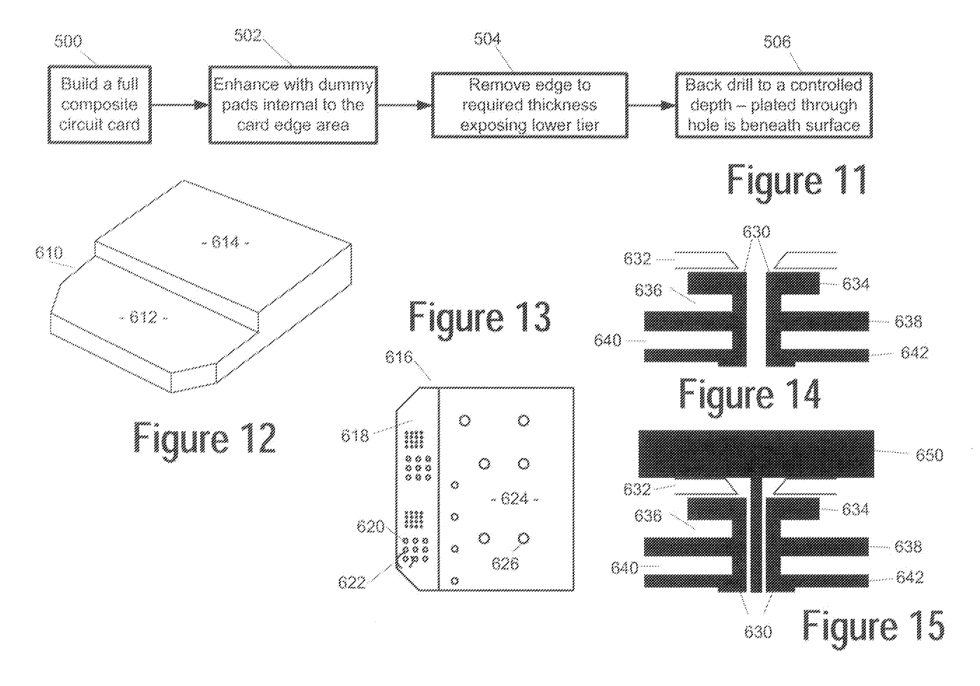

Another embodiment process of the full composite circuit board structure fabrication is shown in FIG. 11. Step 500 provides for the building of the full composite circuit board as before. In step 502, dummy pads are added internally to the areas that will provide the connection to the printed circuit board in step 506. In the preferred embodiment, dummy pads are etched from an extra thick wiring layer in the full composite circuit board. In step 504, an edge portion of the printed circuit board structure is removed to provide a thinner depth printed circuit board portion for interconnection with the printed circuit board connector. As discussed previously, this removal is accomplished by a milling operation resulting in the desired thinner depth according to the preferred embodiment. However, other removal techniques may also be be used such as a grinding operation. In step 506, the laminated layer above the plated through holes are back drilled or countersunk to expose the top electrically conductive area of the plated through holes providing more reliable electrical interconnections to the printed circuit board connector that will be place on the lower tier portion.

This process of FIG. 11 results in a two-tiered printed circuit board 610 shown in FIG. 12. This structure 610 includes the thicker portion 614 and the thinner portion 612. The portion 612 provides for connection to the printed board connector.

In FIG. 13, a top view of the structure is shown which is similar to the structure of FIG. 8. An upper tier area 624 includes plated through holes that selectively eclectically connect all the conductive layers of the full composite structure 616. A portion of the lower tier or thinner portion 618 provides plated through hole structures such as 624 for connection to the printed circuit board connector. An area 622 of this lower tier 618 includes a plated through hole and is shown in cross section in FIG. 14.

In FIG. 14, the laminate non-conductive layer 632 is shown after a countersink drill operation has been performed to expose the plated through hole area 630. This structure provides more of an eclectically conductive area for the printed circuit board connector interconnection resulting in a more reliable connection. In FIG. 14, the printed circuit board cross section includes the non-conductive layers 636 and 640 separating the electrically conductive layers 634, 638 and 642 which can be selectively interconnected to the plated through holes such as 630. In FIG. 15, the cross section of FIG. 14 is shown with an additional printed circuit board connector 650 mounted on the lower tier surface and having a pin that can be electrically connected by solder to the plated through hole 630. The additional exposed metal area from the countersink drilling provides a more robust design and solder contact ability while avoiding delamination of layer 632. This results in long term reliability since it also addressed thermal expansion of the plated through hole 630.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be implemented substantially concurrently, or the blocks may sometimes be implemented in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While particular embodiments of the present invention have been shown and described, it will be obvious to those skilled in the art that, based upon the teachings herein, that changes and modifications may be made without departing from this invention and its broader aspects. Therefore, the appended claims are to encompass within their scope all such changes and modifications as are within the true spirit and scope of this invention. Furthermore, it is to be understood that the invention is solely defined by the appended claims. It will be understood by those with skill in the art that if a specific number of an introduced claim element is intended, such intent will be explicitly recited in the claim, and in the absence of such recitation no such limitation is present. For non-limiting example, as an aid to understanding, the following appended claims contain usage of the introductory phrases “at least one” and “one or more” to introduce claim elements. However, the use of such phrases should not be construed to imply that the introduction of a claim element by the indefinite articles “a” or “an” limits any particular claim containing such introduced claim element to inventions containing only one such element, even when the same claim includes the introductory phrases “one or more” or “at least one” and indefinite articles such as “a” or “an”; the same holds true for the use in the claims of definite articles.

1. A printed circuit board assembly comprising:
a first printed circuit board portion of a first thickness including a first plurality of conductive layers separated by one of a second plurality of nonconductive layers; and
a second printed circuit board portion having a second thickness less than the first thickness and further including at least a first plated through hole exposed on a surface of the second printed circuit board portion and electrically connected to at least one conductive layer.

2. The printed circuit board assembly according to claim 1 wherein said exposed second board portion includes a printed circuit board connector electrically connected to the at least first exposed plated though hole and mounted upon the second printed circuit board portion surface.

3. The printed circuit board assembly according to claim 2 wherein the at least first exposed plated though hole is selectively electrically connected to at least a second plated through hole located in said first printed circuit board portion.

4. The printed circuit board assembly according to claim 1 wherein the at least first exposed plated though hole includes an exposed surface area that a wall thickness of the plated through hole.

5. The printed circuit board assembly according to claim 1 wherein the at least first exposed plated through hole is electrically connected to an electrically conductive metal area adjacent to the exposed portion of the at least first exposed plated through hole.

6. A method for fabricating a printed circuit board assembly comprising the steps of:
forming a printed circuit board of a first thickness having a first plurality of wiring layers separated by one of a second plurality nonconductive layers and further including at least one electrical connection interconnecting at least two of the wiring layers and extending through a one of the nonconductive layers; and
removing a portion of the printed circuit board surface to form a printed circuit board tier having a second thickness being less than the first thickness and exposing the nonconductive layer with the extending portion of the at least one electrical connection.

7. A method for fabricating a printed circuit board assembly according to claim 6 wherein the at least one electrical connection interconnecting at least two of the wiring layers includes a plated through hole.

8. A method for fabricating a printed circuit board assembly according to claim 6 further including the step of mounting a connector upon the removed portion of the printed circuit board and electrically connecting the connector to the at least one electrical connection.

9. A method for fabricating a printed circuit board assembly according to claim 8 further including the step for fabricating a second electrical interconnection located upon a portion of the printed circuit board having the first thickness which is electrically interconnected to the first electrical connection.

10. A method for fabricating a printed circuit board assembly according to claim 9 wherein the first and second interconnections are plated through holes.

11. A method according to claim 10 wherein said adjacent wiring layer is fabricated having a greater thickness that the other printed circuit board wiring layer thicknesses.

12. A printed circuit board assembly comprising:
a first printed circuit board portion of a first thickness including a first plurality of wiring layers separated by one of a second plurality of supporting nonconductive layers; and
a second printed circuit board portion having a second thickness less than the first thickness and further including at least at least two wiring layers and separated by a support layer and a first plated through hole exposed on a surface of the second printed circuit board portion wherein the second printed board surface is a nonconductive layer except for the exposed plated through hole.

13. The printed circuit board assembly according to claim 12 wherein said second printed circuit board portion includes a wiring layer adjacent the surface nonconductive layer and being electrically connected to the plated through hole and further having an area being exposed with the exposed plated through hole.

14. The printed circuit board assembly according to claim 13 wherein said exposed second board portion includes a printed circuit board connector electrically connected to the at least second exposed plated though hole and mounted upon the exposed second printed circuit board portion surface.

15. The printed circuit board assembly according to claim 14 wherein the at least second exposed plated though hole is selectively electrically connected to at least one wiring layer of said first printed circuit board portion.

16. A method for fabricating a printed circuit board assembly comprising the steps of:
forming a printed circuit board of a first thickness having a first plurality of wiring layers separated by one of a second plurality of nonconductive layers and further including at least one electrical connection interconnecting at least two of the wiring layers and extending through a nonconductive layer terminating in a wiring layer having a thickness greater than the thickness of other wiring layers;
removing a portion of the printed circuit board surface to form a printed circuit board tier having a second thickness being less than the first thickness and exposing the nonconductive layer directly above the electrical connection and the wiring layer having a greater thickness; and
removing a portion of the exposed nonconductive layer to expose the electrical connection.

17. A method for fabricating a printed circuit board assembly according to claim 16 wherein the at least one electrical connection interconnecting at least two of the wiring layers includes a plated through hole.

18. A method for fabricating a printed circuit board assembly according to claim 16 further including the step of mounting a connector upon the removed portion of the printed circuit board and electrically connecting the connector to the at least one electrical connection.

19. A method for fabricating a printed circuit board assembly according to claim 16 further including the step for fabricating a second electrical interconnection located upon a portion of the printed circuit board having the first thickness which is electrically interconnected to the first electrical connection.

20. A method for fabricating a printed circuit board assembly according to claim 19 wherein the first and second interconnections are plated through holes.

21. A method for fabricating the printed circuit board assembly according to claim 20 wherein said wherein said step of removing a portion of the printed circuit board surface includes a milling operation.

22. A method for fabricating a printed circuit board assembly according to claim 21 wherein said step of removing a portion of the exposed nonconductive layer includes a countersink drilling operation.

23. A method for fabricating a printed circuit board configuration comprising the steps of:
forming a first sub-composite printed circuit board having a connector area and having a first plurality of wiring layers each separated by one of a second plurality of nonconductive layers;
forming a second sub-composite printed circuit board having a third plurality of wiring layers each separated by one of a fourth plurality of nonconductive layers;
placing a release sheet over the first sub composite printed circuit board connector area;
forming a lamination layer over the first sub-composite printed circuit board and release sheet;
placing the second sub composite printed circuit board on top of the lamination layer; and
removing the portion of the second sub-composite printed circuit board located over the release sheet and the release sheet to expose the connector area of the first printed circuit board.

24. A method for fabricating a printed circuit board configuration according to claim 23 wherein the step of forming the first sub-composite printed circuit board includes forming a first plated through hole electrically connected to at least one of the wiring layers.

25. A method for fabricating a printed circuit board configuration according to claim 23 wherein the step of removing the portion of the second sub-composite printed circuit board includes a milling operation.

26. A method for fabricating a printed circuit board configuration according to claim 23 further including the step of forming a second plated through hole selectively electrically connecting at least one wiring layer of the first sub-composite printed circuit board and at least one wiring layer of the second sub-composite printed circuit board.

27. A printed circuit board assembly comprising:
a first sub-composite printed circuit board having a connector area and having a first plurality of wiring layers each separated by one of a second plurality of nonconductive layers with a first plated through hole located in the connector area and electrically connected to at least one of the wiring layers;
a second sub-composite printed circuit board on top of a lamination layer on top of the first sub composite printed circuit board exposing the connector layer, said second sub-composite printed circuit board including a third plurality of wiring layers each separated by one of a fourth plurality of nonconductive layers.

28. A printed circuit board assembly according to claim 27 further including a second plated through hole electrically connected at least one wiring layer of the first sub-composite printed circuit board and at least one wiring layer of the second sub-composite printed circuit board.
